(19) United States
(12) Patent Application Publication
(10) Pub. No.: US 2002/0170743 A1
(43) Pub. Date: Nov. 21, 2002

(54) Integrated inductance

(75) Inventor: Samuel Boret, Crolles (FR)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics S.A., Montrouge (FR)

(21) Appl. No.: 10/117,463

(22) Filed: Apr. 5, 2002

(30) Foreign Application Priority Data
Apr. 6, 2001 (FR) 01/04689

(51) Int. Cl. H05K 1/00

(52) U.S. Cl. 174/250

(57) ABSTRACT

An inductance device in monolithic structure is formed from a first metallization level layer of lower parallel conductive lines extending along the inductance pattern; next, on a second level, a set of vias is formed over each underlying conductive line being associated with at least two vias; and in a third metallization level, upper conductive lines interconnected to the underlying conductive lines by means of vias, the lower and upper conductive lines being shifted with respect to one another to ensure the electric continuity.

### BACKGROUND OF THE INVENTION

1. Field of the Invention

The present invention generally relates to the forming of inductive windings (inductances) on an integrated circuit chip. More specifically, the present invention relates to the forming of inductances intended to receive hyperfrequency signals intended, for example, for mobile phone receive systems.

2. Description of the Related Art

FIGS. 1A to 1D illustrate, in a partial simplified cross-section view, the forming of an inductance according to a conventional spiral. More specifically, FIGS. 1A to 1D are cross-section views along the width of an inductance spiral.

As illustrated in FIG. 1A, a trench having a width W is first opened in an insulating layer 10 according to the inductance pattern. A layer of a conductive material 11 is then deposited to completely fill the previously-opened trench.

At the next steps, illustrated in FIG. 1B, layer 11 is etched to be removed from the upper surface of insulating layer 10. For this purpose, a chem-mech polishing (CMP) is performed. A first horizontal conductive level 12 has thus been formed. As discussed previously, FIG. 1 is a cross-section view along the width of a spiral of the inductance. First level 12 extends over the entire inductance pattern, and is common to all its spirals. Then, an insulating layer 13 is deposited. Layer 13 is deposited so that its upper surface is substantially planar.

As illustrated in FIG. 1C, distinct openings are formed in layer 13 to partially expose different portions of the upper surface of first level 12. Then, these openings are filled with a conductive material 14, preferably identical to conductive material 11 forming first level 12.

After deposition over the entire structure of material 14, a chem-mech polishing is performed to remove material 14 from the upper surface of insulating layer 13.

Parallel conductive vias 16 in contact with first level 12 are thus individualized, as illustrated in FIG. 1D. Then, an insulating layer 17 is deposited so that its upper surface is substantially planar. A second horizontal conductive level 18 is then formed above first level 12 and interconnects all vias 16. Second level 18 is formed by opening a trench according to an appropriate pattern in insulating layer 17, then by depositing a conductive material, preferably identical to conductive material 11, and finally performing a chem-mech polishing (CMP) to only maintain in place the copper in the previously-formed trench.

An inductance with spirals including first and second horizontal conductive levels 12 and 18 interconnected by vias 16 is thus formed in an integrated circuit chip. Interconnection lines or vias may be formed in insulating layers 10, 13, and/or 17 simultaneously with first level 12, with vias 16 and/or with second level 18.

In applications of telecommunication type, inductances are, conversely, deposited above integrated circuits, no other conductive element being formed in insulating layers 10, 13, and 17 above the region occupied by the inductance. Such inductances, intended to be used in hyperfrequency devices, must exhibit a maximum quality factor Q and be able to operate at an optimal resonance frequency and/or in the widest possible frequency band.

Increasing factor Q leads to reducing the resistance of the inductance. For this purpose, it has already been provided, as a conductive material forming levels 12 and 18 and vias 16, a lightly resistive materials such as copper or copper-based alloys. To further reduce the resistivity, it has then been provided to increase the surface area of levels 12 and 18 and of vias 16. This increase being impossible in the thickness of successive layers 10, 13, 17 determined by other standard constraints of micro-electronics methods, the widest possible levels 12 and 18 have been formed in layers 10 and 17, correspondingly increasing the number of vias 16 in layer 13. However, such a width increase of levels 12 and 18 is limited by the chem-mech polishing implemented to individualize the spirals in each layer. Indeed, in a CMP of a relatively wide copper surface, a deformation of this surface can be observed. More specifically, this deformation results in the forming of a hole with a poorly defined depth and extent. The real resistance of the line run through by a given current is then increased and quality factor Q is decreased. This decrease in quality factor Q is uncontrolled. Further, if the surface area is too large, this deformation may occur to the extent of tearing up the conductive line. This results in a spiral breakage.

Further, when a high-frequency electric current is attempted to be run through a conductor, the current tends to only flow at the periphery of the conductive volume (skin effect). In other words, for high-frequency currents, instead of taking advantage of the entire conductive surface, the current limits to a small peripheral surface. Everything then occurs as if the current would flow in a conductor of high real resistance, that is, of lowered quality factor.

Currently, given the various previously-discussed problems, inductances are comprised of levels with a cross-section of at most 14 μm² and currents having an intensity on the order of 56 mA.

At the same time, the desire to transmit a higher and higher number of data and the frequency range congestion, leads to searching communication systems adapted to operating at the highest possible frequencies with optimized quality factors.

### BRIEF SUMMARY OF THE INVENTION

An embodiment of the present invention provides an inductance formed in an integrated circuit chip, having a perfectly controlled quality factor.

The embodiment of the present invention provides such an inductance, the manufacturing of which inscribes in the step sequence currently implemented in the manufacturing of the metallizations of an integrated circuit.

To achieve these embodiments, the present invention provides an inductance in monolithic form, including:

in a first metallization level, lower parallel conductive lines extending along the inductance pattern;

in a second level, vias, each underlying conductive line being associated with at least two vias; and

in a third metallization level, upper conductive lines interconnected to the underlying conductive lines by means of vias, the lower and upper conductive lines being shifted with respect to one another to ensure the electric continuity.

The present invention also provides a method for forming an inductance in monolithic form, including the steps of:

forming, in a first metallization level, first parallel conductive lines according to the inductance pattern;

forming, in a second metallization level, vias, so that each underlying conductive line contacts at least two vias; and

forming, in a third metallization level, second conductive lines, according to the inductance pattern, the second lines being shifted with respect to the first lines to contact vias associated with distinct first lines.

According to an embodiment of the present invention, the forming of lines or vias in a given metallization level includes the steps of:

digging into an insulating layer according to the desired pattern;

depositing a layer of a conductive material to fill the previously-formed openings; and

performing a chem-mech polishing, to remove said conductive material from the upper surface of said considered insulating layer, whereby the conductive material only remains in place in the previously-formed openings.

According to an embodiment of the present invention, the conductive material is a metal.

According to an embodiment of the present invention, the conductive material is copper or a copper-based alloy.

The foregoing embodiments, features and advantages of the present invention will be discussed in detail in the following non-limiting description of specific embodiments in connection with the accompanying drawings.

### BRIEF DESCRIPTION OF THE SEVERAL VIEW OF THE DRAWINGS

FIGS. 1A to 1D illustrate prior art, in partial simplified cross-section views, different manufacturing steps of an inductance according to conventional methods;

FIGS. 2A to 2D illustrate an embodiment of the present invention, in partial simplified cross-section views, an inductance according to the present invention at different steps of its forming.

FIG. 3 illustrates a top plan view of an inductor pattern of an embodiment of the invention.

FIG. 4 illustrates a cross section view of multiple segments of an embodiment of the invention at the location shown in FIG. 3 by lines 4-4.

FIG. 5 illustrates a top plan view of a segment of the inductor pattern of an embodiment of the invention as shown in FIG. 3.

### DETAILED DESCRIPTION OF THE INVENTION

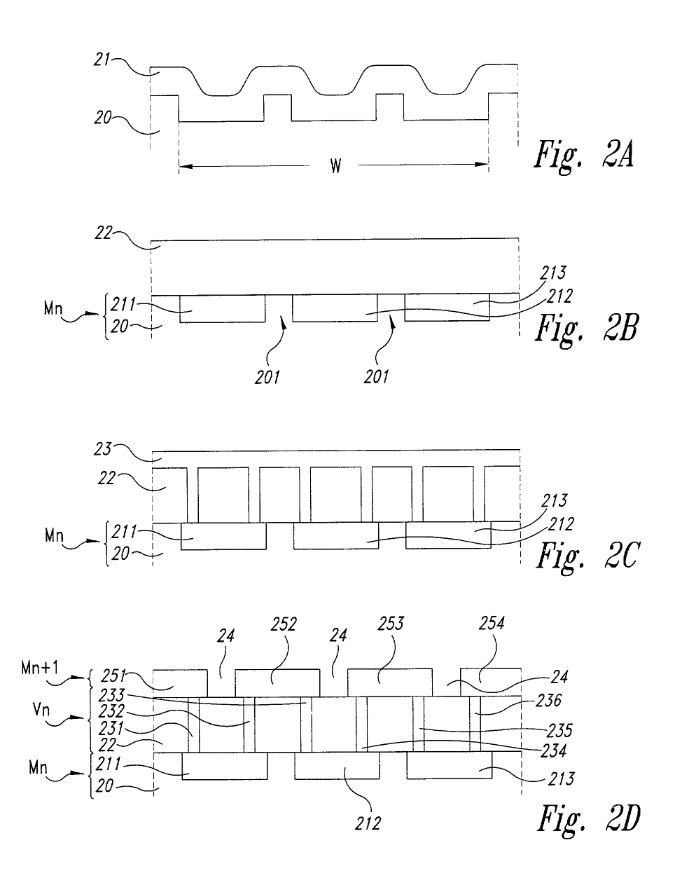

As illustrated in FIG. 2A, the method according to the present invention starts with the forming, in an insulating layer 20, of parallel trenches. The dimensions of these trenches will be discussed hereafter in relation with FIG. 2C. Layer 20 is superposed to a semiconductor substrate (not shown), for example, made of single-crystal silicon, in which various elements are integrated. Layer 20 is preferably formed not directly on the substrate, but above at least one metallization level.

Then, a conductive material 21, preferably a metal, for example copper or a copper-based alloy, is deposited over the entire structure to completely fill the previously-formed trenches.

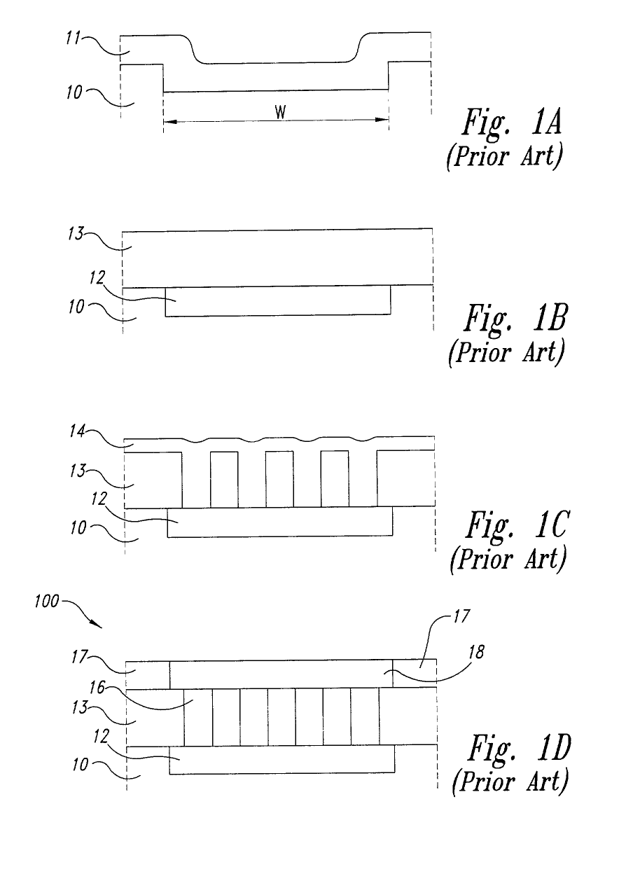

At the next steps, illustrated in FIG. 2B, material 21 is etched to only be maintained in place in the trenches. Material 21 is completely removed from the upper surface of insulating layer 20. For this purpose, a chem-mech polishing (CMP) is for example performed. Parallel conductive lines separated by insulating portions 201 are thus formed in a first metallization level Mn. In FIG. 2, three conductive lines 211, 212, 213 have been shown. It will be ascertained, as illustrated in FIG. 2A, that the sum of the widths of the different individual lines 211, 212, 213 and of insulating portions 201 is equal to width W of a conventional spiral, that is, of the first level (12, FIG. 1) according to prior art. Then, an insulating layer 22 is deposited so that its upper surface is substantially planar.

At the next steps, illustrated in FIG. 2C, openings are formed in insulating layer 22 so that the upper surface of a conductive line 211, 212, 213 is at least partially exposed. More specifically, insulating layer 22 is opened so that each conductive line 211, 212, 213 is exposed twice along its cross-section. Then, a lightly resistive conductive layer 23, preferably, a metal, for example, copper or a copper alloy, is deposited over the entire structure.

Then, as illustrated in FIG. 2D, a CMP is performed to remove material 23 from the upper surface of insulating layer 22. A level of vias Vn has thus been formed, in which different vias 231, 232, 233, 234, 235, 236 are embedded in an insulating layer 22. Each line 211, 212, 213 of lower metallization level Mn is associated with two such vias. For example, conductive line 211 is in contact with vias 231 and 232. Line 212 is in contact with vias 233 and 234. Line 213 is in contact with vias 235 and 236.

Then, an insulating layer 24 is deposited and the steps previously described in relation with FIGS. 2A and 2B of forming of conductive lines according to the inductance pattern are repeated. However, as compared to FIG. 2A, the pattern of conductive lines 251, 252, 253, and 254 thus formed in a metallization level Mn+1 superposed to level Vn is shifted with respect to the pattern of lines 211, 212, and 213 of the underlying metallization level Mn at the level of vias Vn. More specifically, each upper line 251, 252, 253, 254 is associated with two vias, each of which is associated with a different underlying conductive line. Thus, in FIG. 2D, upper conductive line 252 is formed in contact with vias 232 and 233, that is, is in electric contact with lower lines 211 and 212. Line 212 is itself in electric contact, through via 234, with upper line 253 which contacts, through via 235, line 213. Lower line 213 contacts in turn, through via 236, the next upper conductive line 254. Thus, there is an electric interconnection between the different lines forming a single conductor across the entire width of the inductance spiral.

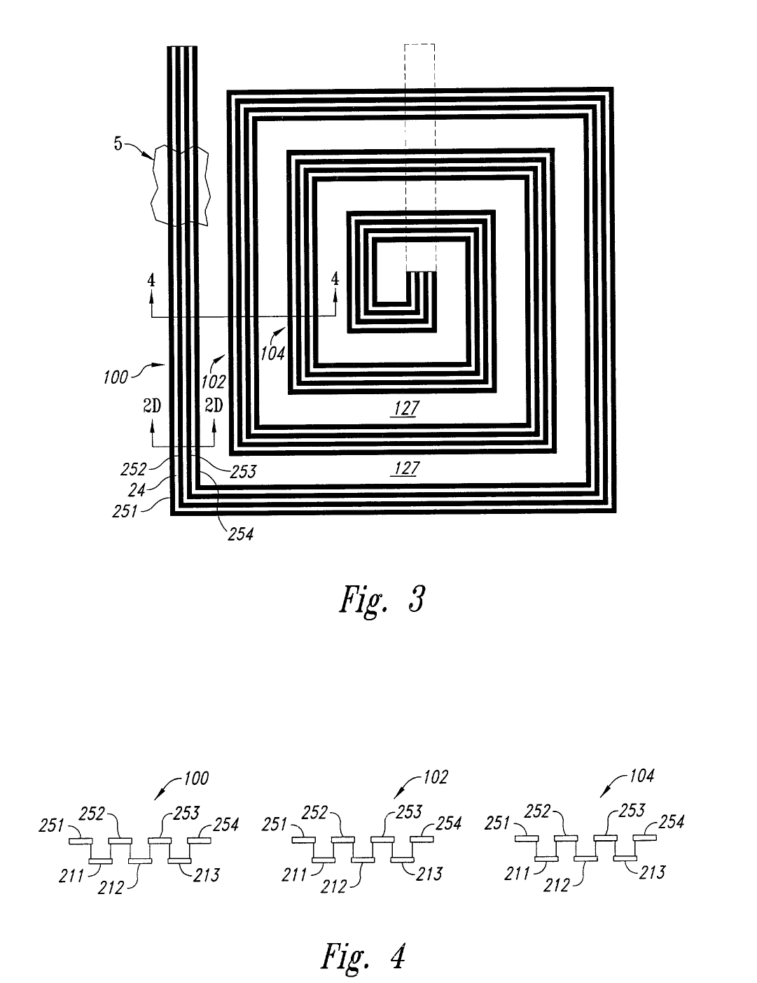

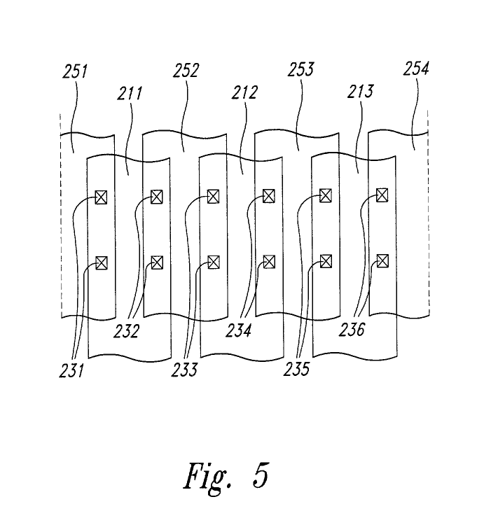

As shown in FIG. 3, carrying out the method according to the present invention forms an embodiment of an inductance pattern. The inductance pattern is composed of segments 100, 102, 104 where each segment has conductive lines 211 through 254. Only the upper conductive lines 251, 252, 253, and 254 are shown in FIG. 4. The inductive pattern may form a rectangular spiral, circular spiral or variations thereof. The number of segments 100, 102, 104 forming a spiral may be increased or decreased as required by the design application. The segment to segment spacing 127 may be formed at the minimum metal to metal spacing allowed by the design rules of the process technology. Alternatively, the spacing 127 between the segments 100, 102, 104 may be increased as desired by the design application. The inductance pattern may be coupled to other devices within the semiconductor substrate in a known manner.

An advantage of the method according to the present invention is that the thickness of conductive material necessary to form individual conductive lines 211, 212, 213, 251, 252, 253, 254 is smaller than the thickness of the homologous layer (11, FIG. 2A) necessary to form a single conductive line across the entire spiral width. This thickness reduction eases the CMP of individualization of the inductance spirals, consisting of eliminating the lightly-resistive conductive material from the upper surface of insulator 20, 24 in which are formed conductive lines 211, 212, 213, and 251, 252, 253, 254.

As shown in FIG. 3, a segment 100, 102, 104 is composed of a plurality of conductive lines where each conductive line is separated by the space 127 of the region of insulating material 24. The width of each conductive line 251, 252, 253, 254, 211, 212, 213 of the segments 100, 102, 104 is small compared to the segment composed of the single solid conductor 12, 18 as shown in FIG. 1. The small width of the conductive lines provides the advantage of reducing the effects of thermal cycling and errors caused by differences in the coefficient of thermal expansion of different materials. It also impacts the effects of the surface tension of the conductive lines. The conductive lines are subject to repeated temperature cycles of heating and cooling during manufacturing and also somewhat during operation. Reducing the surface tension and the results of thermal effects on the conductive lines thus reduces manufacturing defects such as pealing and cracking of the conductive lines. Another advantage of the present invention is that by so forming a copper line pattern of restricted width separated by an insulator, sinking and/or tearing risks are considerably attenuated during subsequent manufacturing steps.

The segment 100 is thus made of a plurality of smaller conductive lines having an effective electrical width of a single, large line with respect to some properties of the inductor. Further, the electrical properties of a group of small lines are improved over the electrical properties of a single large line, so the metal width itself is less for the same electrical properties. As shown in FIG. 4, an embodiment of the present invention is formed of segments 100, 102, 104 where each segment is composed of a first level of conductive lines 211, 212, 213 and second level of conductive lines 251, 252, 253, 254. Each conductive line is coupled to at least two vias as describe in FIG. 3. An advantage of the structure and method of the present invention is that the number of metal layers can be increase to form additional conductive lines. For example, a third metal layer of conductive lines could be formed above the second level of conductive lines. The third metal layer of conductive lines could be coupled to the second level of conductive lines by a second level of vias. The third layer of conductive lines could be positioned as a mirror of the first conductive lines. Thus an inductor having a improved Q-factor can be formed.

The present invention accordingly enables forming an inductance having an increased width with a perfectly controlled quality factor. Indeed, to increase the spiral width, instead, according to prior art, of increasing the width of a continuous copper surface, the number of parallel lines formed in each of metallizations levels Mₙ, Mₙ+1 is increased. As shown in FIG. 35, there are three lower metal lines 211, 252, 213 and four upper metal lines 251, 252, 253, 254. To increase the spiral width, the number of conductive lines of the lower and upper metal layers is increased in the surface of insulator 20 while maintaining the width of each conductive metal line. Alternatively, to increases the spiral width, the width of each conductive line in the upper and lower layers can be increased beyond the minimum design rule width and spacing allowed by the process technology. Finally, to increase the spiral width, the number of segments 100, 102, 104 can be increased thereby increasing the number of spirals in the inductor pattern while maintaining the width of the conductive lines.

An enlarged top plan view of a segment of the inductor pattern is shown in FIG. 5 from the location shown in FIG. 3. The segment is composed of lower conductive lines 211, 212, 213 in a lower metal layer and upper conductive lines 251, 252, 253, 254 in an upper metal layer. Vias 231, 232, 233, 234, 235, 236 couple the upper and lower conductive lines of the segment. The upper conductive lines are separated by insulating layer 24 as describe in FIG. 2D. The lower conductive lines are separated by insulating regions 201 as described in FIG. 2B. The number of vias coupling the upper and lower conductive lines can be increased by reducing the via to via spacing to the minimum via spacing of the design rules allowed by the process technology. Further, the aspect ratio of the vias may vary from values of 1, 0.5, 1.5 or larger to provide an improved conductive via structure between the various upper and lower conductive lines. By increasing the number of vias , the capacitive cross coupling between conductive lines will be reduced. For example, in a preferred embodiment, the height of the vias as controlled by the height of insulating layer 22 will be a minimum allowed by the process technology. Minimizing the height of the vias reduces the resistance between metal conductor lines in the upper and lower metal layers and improves the conductivity of the inductance pattern. It will be ascertained during the forming of vias 231, 232, 233, 234, 235, and 236 to provide as many vias as necessary to ensure a homogeneous distribution of the currents and a homogenization of the voltages, to avoid any possible capacitive coupling between lines of a same level.

Of course, the present invention is likely to have various alterations, modifications, and improvements which will readily occur to those skilled in the art. In particular, when numerical examples have been given, these numerical examples do not aim at limiting the present invention to such examples. Further, those skilled in the art will be able to form, if necessary, in each of the various levels Mn, Vn, and Mn+1, outside of the inductance forming region, any other element necessary to the device operation. They will also be able to provide elements adapted to avoiding any capacitive coupling between the inductance and other elements formed in the same integrated circuit chip. Further, the inductance may be formed of more than two levels Mn, Mn+1, provided that the alternated structure of the contacts between the different levels is respected.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An inductance formed in metal layers of an integrated circuit, made of a winding wound in a plane parallel with the main surface of the integrated circuit, wherein said winding comprises:
in a first metallization level, lower parallel conductive lines extending along an inductance pattern;
in a second level, vias, each lower conductive line being associated with at least two vias; and
in a third metallization level, upper conductive lines interconnected to the lower conductive lines by means of vias, the lower and upper conductive lines being shifted with respect to one another to ensure the electric continuity.

2. A method for forming an inductance in monolithic form, including the steps of:
forming, in a first metallization level, first parallel conductive lines according to an inductance pattern;
forming, in a second metallization level, vias, so that each underlying conductive line contacts at least two vias; and
forming, in a third metallization level, second conductive lines according to the inductance pattern, the second lines being shifted with respect to the first lines to contact vias associated with distinct first lines.

3. The method of claim 2, wherein the forming of lines or vias in a given metallization level includes the steps of:
etching into an insulating layer according to the desired pattern;
depositing a layer of a conductive material to fill the previously-formed openings; and
performing a chem-mech polishing, to remove said conductive material from the upper surface of said considered insulating layer, whereby the conductive material only remains in place in the previously-formed openings.

4. The method of claim 3, wherein the conductive material is a metal.

5. The method of claim 4, wherein the conductive material is copper or a copper-based alloy.

6. An inductance device having a length of an inductance pattern in a semiconductor substrate comprising:
a plurality of first conductive lines wherein the first conductive lines are formed in the inductance pattern wherein each first conductive line is parallel to another first conductive line;
a plurality of vias wherein at least two of the vias are coupled to the first conductive line of the first plurality of conductive lines;
a plurality of second conductive lines, each second conductive line being parallel to another second conductive line and to the plurality of first conductive lines, wherein the second conductive lines, being coupled to at least two vias of the plurality of vias, are offset from and overlap the first conductive lines for the length of the inductance pattern.

7. A method of forming an inductance device having a length of an inductance pattern on a semiconductor substrate comprising the steps of:
forming a first metallization layer of a plurality of first conductive lines over a first surface of the inductance device wherein the first conductive lines are formed the inductance pattern, each first conductive line being parallel to another first conductive line
forming a plurality of vias wherein at least two vias are coupled to each of the first conductive lines;
forming a second metallization layer over a second surface wherein the plurality of vias is filled; and
forming a third metallization layer of a plurality of second conductive lines, each second conductive line being parallel to another conductive line and to the plurality of first conductive lines, wherein the second conductive lines, being coupled to at least two vias of the plurality of vias, are offset from and overlap the first conductive lines for the length of the inductance pattern.

8. A method of forming an inductance device according to claim 7 wherein the step of forming the first metallization layer includes the steps of:
removing a portion of an insulating layer wherein the removed portion is an inductance pattern;
depositing a layer of a conductive material over a surface of the inductance device to fill the removed portion of the insulating layer; and
polishing the surface of the inductance device wherein the conductive material is removed and the conductive material remains only in the removed portion of the insulating layer.

9. A method of forming an inductance device according to claim 7 wherein the step of forming the third metallization layer includes the step of:
polishing the surface of the inductance device wherein the conductive material is removed and the conductive material remains only in the plurality of vias.

10. The method of forming an inductance device according to claim 7 wherein the conductive material is a metal.

11. The method of forming an inductance device according to claim 10 wherein the conductive material is metal.

12. The method of forming an inductance device according to claim 8 wherein the step of forming the first metallization layer includes the step of:
depositing an insulating layer thus forming a surface that is substantially planar.

13. An inductance device having a length of an inductance pattern comprising:
a plurality of first conductive lines wherein the first conductive lines are formed in the inductance pattern wherein each first conductive line is parallel to another first conductive line for the length of the inductance pattern;
a plurality of vias wherein at least two of the vias are coupled to the first conductive line of the first plurality of conductive lines, and each via having an aspect ratio such that the via is in electrical communication with the first conductive line of the first plurality of conductive lines for the length of the inductance pattern;
a plurality of second conductive lines, each second conductive line being parallel to another second conductive line and to the plurality of first conductive lines, wherein the second conductive lines, being in electrical communication with at least two vias of the plurality of vias for the length of the inductance pattern, are offset from and overlap the first conductive lines for the length of the inductance pattern.

14. The inductance device according to claim 13 wherein the first and second conductive lines are formed of a metal.

15. The inductance device according to claim 14 wherein the first and second conductive lines are formed of copper, a copper alloy, aluminum or gold.

16. The inductance device according to claim 13 wherein each via of the plurality of vias is formed of a contact opening and a metal region.

17. The inductance device according to claim 16 wherein the via is formed of a metal.

18. The inductance device according to claim 17 wherein the via is formed of copper, a copper alloy, aluminum, tungsten or gold.
